(19) United States
(12) Patent Application Publication
(10) Pub. No.: US 2024/0005998 A1
(43) Pub. Date: Jan. 4, 2024

(54) MEMORY DEVICE AND OPERATING METHOD THEREOF

(71) Applicant: SK hynix Inc., Icheon-si Gyeonggi-do (KR)

(72) Inventor: Byoung Jun PARK, Icheon-si Gyeonggi-do (KR)

(73) Assignee: SK hynix Inc., Icheon-si Gyeonggi-do (KR)

(21) Appl. No.: 17/987,555

(22) Filed: Nov. 15, 2022

(30) Foreign Application Priority Data
Jun. 29, 2022 (KR) 10-2022-0080069

(51) Int. Cl. G11C 16/20; G11C 16/32; G11C 16/24; G11C 16/30

(52) U.S. Cl. CPC G11C 16/20; G11C 16/32; G11C 16/24; G11C 16/30

(57) ABSTRACT

A memory device, and an operating method thereof, includes a memory cell array including a plurality of memory blocks and peripheral circuits for performing a program operation, a read operation, or an erase operation on the plurality of memory blocks. The memory device and method also includes a negative voltage generating circuit for applying a negative voltage to bit lines or a source line of the plurality of memory blocks or the bit lines and the source line in a negative voltage applying operation. The memory device and method further includes control logic for controlling the peripheral circuits to perform the program operation, the read operation, or the erase operation, and controlling the negative voltage generating circuit to perform the negative voltage applying operation after a power-on operation.

### CROSS-REFERENCE TO RELATED APPLICATION

The present application claims priority under 35 U.S.C. § 119(a) to Korean patent application number 10-2022-0080069, filed on Jun. 29, 2022, in the Korean Intellectual Property Office, the entire disclosure of which is incorporated herein by reference.

### BACKGROUND

### 1. Technical Field

The present disclosure generally relates to an electronic device, and more particularly, to a memory device and an operating method thereof.

### 2. Related Art

The paradigm on recent computer environment has been turned into ubiquitous computing environment in which computing systems can be used anywhere and anytime. This promotes increasing usage of portable electronic devices such as mobile phones, digital cameras, notebook computers, and the like. Such portable electronic devices may generally include a memory system using a memory device, i.e., a data storage device. The data storage device may be used as a main memory device or an auxiliary memory device of the portable electronic devices.

A data storage device using a memory device has excellent stability and durability, high information access speed, and low power consumption, since there is no mechanical driving part. In examples of memory systems having such advantages, the data storage device includes a Universal Serial Bus (USB) memory device, memory cards having various interfaces, a Solid State Drive (SSD), and the like.

The memory device is generally classified as a volatile memory device or a nonvolatile memory device.

The nonvolatile memory device has relatively slow write and read speeds, but retains stored data even when the supply of power is interrupted. Thus, the nonvolatile memory device is used to store data to be retained regardless of whether power is supplied. Examples of nonvolatile memory include Read Only Memory (ROM), Mask ROM (MROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), Ferroelectric RAM (FRAM), and the like. Flash memory is classified as NOR type flash memory or NAND type flash memory.

### SUMMARY

Some embodiments provide a memory device capable of applying a negative voltage to bit lines and a source line of memory blocks so as to prevent a read fail of a first page of a share block, which occurs after a program, read or erase operation is performed on a target block, and an operating method of the memory device.

In accordance with an embodiment of the present disclosure, a memory device includes: a memory cell array including a plurality of memory blocks; peripheral circuits configured to perform a program operation, a read operation, or an erase operation on the plurality of memory blocks; a negative voltage generating circuit configured to apply a negative voltage to bit lines or a source line of the plurality of memory blocks or the bit lines and the source line in a negative voltage applying operation; and control logic configured to control the peripheral circuits to perform the program operation, the read operation, or the erase operation, and control the negative voltage generating circuit to perform the negative voltage applying operation after a power-on operation.

In accordance with the present disclosure is a method of operating a memory device, the method including: performing a power-on operation to power up the memory device as a power voltage is supplied to the memory device from outside the memory device; and performing a negative voltage applying operation of applying a negative voltage to bit lines or a source line of the plurality of memory blocks or the bit lines and the source line.

In accordance with the present disclosure is a method of operating a memory device, the method including: performing a power-on operation to power up the memory device as a power voltage is supplied to the memory device from outside the memory device; performing a negative voltage applying operation of applying a negative voltage to bit lines or a source line of the plurality of memory blocks or the bit lines and the source line; and re-performing the negative voltage applying operation when a setting time elapses after the negative voltage applying operation is performed.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system in accordance with an embodiment of the present disclosure.

FIG. 2 is a diagram illustrating a memory device shown in FIG. 1.

FIG. 3 is a diagram illustrating a memory block shown in FIG. 2.

FIG. 4 is a diagram illustrating an embodiment of a three-dimensionally configured memory block.

FIG. 5 is a flowchart illustrating an operating method of the memory device in accordance with an embodiment of the present disclosure.

FIG. 6 is a flowchart illustrating an operating method of the memory device in accordance with another embodiment of the present disclosure.

FIG. 7 is a diagram illustrating another embodiment of the memory system.

FIG. 8 is a diagram illustrating another embodiment of the memory system.

FIG. 9 is a diagram illustrating another embodiment of the memory system.

FIG. 10 is a diagram illustrating another embodiment of the memory system.

### DETAILED DESCRIPTION

The specific structural or functional description disclosed herein is merely illustrative for the purpose of describing embodiments according to the concept of the present disclosure. Embodiments according to the concept of the present disclosure can be implemented in various forms, and should not be construed as being limited to the embodiments set forth herein.

Hereinafter, embodiments of the present disclosure will be described in detail with reference to the accompanying drawings in order for those skilled in the art to be able to readily implement the technical spirit of the present disclosure.

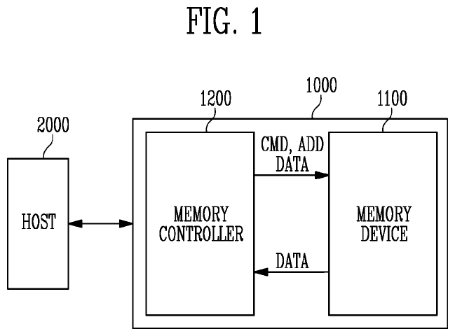

FIG. 1 is a diagram illustrating a memory system in accordance with an embodiment of the present disclosure.

Referring to FIG. 1, the memory system 1000 may include a memory device 1100 configured to store data and a memory controller 1200 configured to control the memory device 1100 under the control of a host 2000.

The host 2000 may communicate with the memory system 1000 by using an interface protocol such as Peripheral Component Interconnect-Express (PCI-E), Advanced Technology Attachment (ATA), Serial ATA (SATA), Parallel ATA (PATA), or Serial Attached SCSI (SAS). In addition, the interface protocol between the host 2000 and the memory system 1000 are not limited to the above-described example, and may be one of other interface protocols such as a Universal Serial Bus (USB), a Multi-Media Card (MMC), an Enhanced Small Disk Interface (ESDI), and an Integrated Drive Electronics (IDE).

The memory controller 1200 may control overall operations of the memory system 1000, and control data exchange between the host 2000 and the memory device 1100. For example, the memory controller 1200 may control the memory device 1100 to program or read data according to a request of the host 2000. In a program operation, the memory controller 1200 may transmit, to the memory device 1100, a command CMD corresponding to the program operation, an address ADD, and data DATA to be programmed. Also, in a read operation, the memory controller 1200 may receive and temporarily store data DATA read from the memory device 1100, and transmit the temporarily stored data DATA to the host 2000.

The memory device 1100 may perform a program, read, or erase operation under the control of the memory controller 1200.

In some embodiments, the memory device 1100 may include Double Data Rate Synchronous Dynamic Random Access Memory (DDR SDRAM), Low Power Double Data Rate4 (LPDDR4) SDRAM, Graphics Double Data Rate (GDDR) SDRAM, Low Power DDR (LPDDR), Rambus Dynamic Random Access Memory (RDRAM), or flash memory.

Also, the memory device 1100 may apply a negative voltage to bit lines and a source line of a plurality of memory blocks included in the memory device 1100 after a power-on operation. Accordingly, holes remaining in channels of strings included in each of the plurality of memory blocks can be removed. This may be defined as a negative voltage applying operation. Also, the memory device 1100 may re-perform the negative voltage applying operation when a setting time elapses after the negative voltage applying operation is performed. Also, the memory device 1100 may re-perform the negative voltage applying operation when a number of times a program/erase cycle of the plurality of memory blocks is repeated exceeds a set number of times after the negative voltage applying operation is performed.

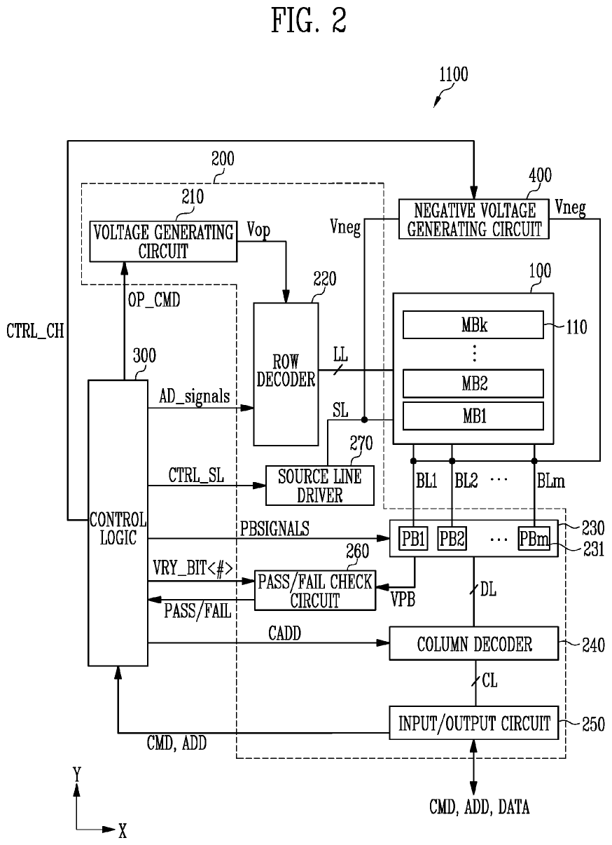

FIG. 2 is a diagram illustrating the memory device shown in FIG. 1.

Referring to FIG. 2, the memory device 1100 may include a memory cell array 100 in which data is stored. The memory device 1100 may include peripheral circuits 200 configured to perform a program operation for storing data in the memory cell array 100, a read operation for outputting stored data, and an erase operation for erasing stored data. The memory device 1100 may include control logic 300 which controls the peripheral circuits 200 under the control of the memory controller (1200 shown in FIG. 1). The memory device 1100 may include a negative voltage generating circuit 400 for applying a negative voltage Vneg to bit lines BL1 to BLm or a source line SL of the memory cell array 100 or the bit lines BL1 to BLm and the source line SL in a negative voltage applying operation.

The memory cell array 100 may include a plurality of memory blocks MB1 to MBk 110 (k is a positive integer). Local lines LL and the bit lines BL1 to BLm (m is a positive integer) may be connected to each of the memory blocks MB1 to MBk 110. For example, the local lines LL may include a first select line, a second select line, and a plurality of word lines arranged between the first and second select lines. Also, the local lines LL may include dummy lines arranged between the first select line and the word lines and between the second select line and the word lines. The first select line may be a source select line, and the second select line may be a drain select line. For example, the local lines LL may include word lines, drain and source select lines, and source lines SL. For example, the local lines LL may further include dummy lines. For example, the local lines LL may further include pipe lines. The local lines LL may be connected to each of the memory blocks MB1 to MBk 110, and the bit lines BL1 to BLm may be commonly connected to the memory blocks MB1 to MBk 110. The memory blocks MB1 to MBk 110 may be implemented in a two-dimensional or three-dimensional structure. For example, memory cells may be arranged in a direction parallel to a substrate in the memory blocks 110 having the two-dimensional structure. For example, memory cells may be stacked in a direction vertical to a substrate in the memory blocks 110 having the three-dimensional structure.

The peripheral circuits 200 may be configured to perform program, read, and erase operations of a selected memory block 110 under the control of the control logic 300. For example, the peripheral circuits 200 may include a voltage generating circuit 210, a row decoder 220, a page buffer group 230, a column decoder 240, an input/output circuit 250, a pass/fail check circuit 260, and a source line driver 270.

The voltage generating circuit 210 may generate various operating voltages Vop used for program, read, and erase operations in response to an operation signal OP_CMD. Also, the voltage generating circuit 210 may selectively discharge the local lines LL in response to the operation signal OP_CMD. For example, the voltage generating circuit 210 may generate a program voltage, a verify voltage, a read voltage, a pass voltage, a plurality of setting voltages, and the like under the control of the control logic 300.

The row decoder 220 may transfer the operating voltages Vop to the local lines LL connected to the selected memory block 110 in response to row decoder control signals AD_signals. For example, in a program operation, the row decoder 220 may apply the program voltage generated by the voltage generating circuit 210 to a selected word line among the local lines LL and apply the pass voltage generated by the voltage generating circuit 210 to unselected word lines, in response to the row decoder control signals AD_signals. In a read operation, the row decoder 220 may sequentially apply a plurality of read voltages generated by the voltage generating circuit 210 to the selected word line among the local lines LL and apply the pass voltage generated by the voltage generating circuit 210 to the unselected word lines, in response to the row decoder control signals AD_signals.

The page buffer group 230 may include a plurality of page buffers PB1 to PBm 231 connected to the bit lines BL1 to BLm. The page buffers PB1 to PBm 231 may be operated in response to page buffer control signals PBSIGNALS. For example, in a program operation, the page buffers PB1 to PBm 231 may temporarily store data to be programmed and control a potential level of the bit lines BL1 to BLm, based on the temporarily stored data to be programmed. Also, in a read or program verify operation, the page buffers PB1 to PBm 231 may sense a voltage or current of the bit lines BL1 to BLm.

The column decoder 240 may transfer data between the input/output circuit 250 and the page buffer group 230 in response to a column address CADD. For example, the column decoder 240 may exchange data with the page buffers 231 through data lines DL, or exchange data with the input/output circuit 250 through column lines CL.

The input/output circuit 250 may transfer a command CMD and an address ADD, which are transferred from the memory controller (1200 shown in FIG. 1) to the control logic 300, or exchange data DATA with the column decoder 240.

In a read operation or a program verify operation, the pass/fail check circuit 260 may generate a reference current in response to an allow bit VRY_BIT<#>, and output a pass signal PASS or a fail signal FAIL by comparing a sensing voltage VPB received from the page buffer group 230 with a reference voltage generated by the reference current. The sensing voltage VPB may be a voltage controlled based on a number of memory cells determined as pass in the program verify operation.

The source line driver 270 may be connected to a memory cell included in the memory cell array 100 through the source line SL, and control a voltage applied to the source line SL. The source line driver 270 may receive a source line control signal CTRL_SL from the control logic 300, and control a source line voltage applied to the source line SL, based on the source line control signal CTRL_SL.

The control logic 300 may control the peripheral circuit 200 by outputting the operation signal OP_CMD, the row decoder control signals AD_signals, the page buffer control signals PBSIGNALS, and the allow bit VRY_BIT<#> in response to the command CMD and the address ADD.

The control logic 300 may generate and output a channel control signal CTRL_CH for controlling the negative voltage generating circuit 400 to perform a negative voltage applying operation after a power-on operation of the memory device 1100. Also, the control logic 300 may generate and output the channel control signal CTRL_CH for controlling the negative voltage generating circuit 400 to re-perform the negative voltage applying operation when a setting time elapses after the negative voltage applying operation is performed. For example, the control logic 300 may control the negative voltage generating circuit 400 to re-perform the negative voltage applying operation during a standby interval of the memory device 1100 when the setting time elapses after the negative voltage applying operation is performed. Also, the control logic 300 may generate and output the channel control signal CTRL_CH for controlling the negative voltage generating circuit 400 to re-perform the negative voltage applying operation when a number of times a program/erase cycle of the plurality of memory blocks MB1 to MBk 110 included in the memory cell array 100 is repeated exceeds a set number of times after the negative voltage applying operation is performed. For example, the control logic 300 may control the negative voltage generating circuit 400 to re-perform the negative voltage applying operation during the standby interval of the memory device 1100 when the number of times the program/erase cycle of the plurality of memory blocks MB1 to MBk 110 is repeated exceeds the set number of times.

The negative voltage generating circuit 400 may apply the negative voltage Vneg to the bit lines BL1 to BLm or the source line SL of the plurality of memory blocks MB1 to MBk 110 or the bit lines BL1 to BLm and the source line of the plurality of memory blocks MB1 to MBk 110 in response to the channel control signal CTRL_CH generated by the control logic 300.

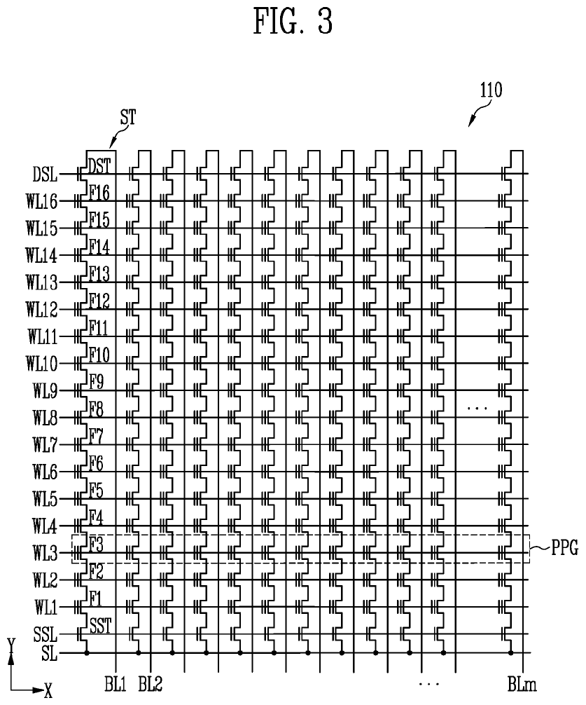

FIG. 3 is a diagram illustrating the memory block 110 shown in FIG. 2.

Referring to FIG. 3, in the memory block 110, a plurality of word lines arranged in parallel to one another may be connected between a first select line and a second select line. The first select line may be a source select line SSL, and the second select line may be a drain select line DSL. More specifically, the memory block 110 may include a plurality of strings ST connected between bit lines BL1 to BLm and a source line SL. The bit lines BL1 to BLm may be connected to the strings ST, respectively, and the source line SL may be commonly connected to the strings ST. The strings ST may be configured identically to one another, and therefore, a string ST connected to a first bit line EL1 will be described in detail as an example.

The string ST may include a source select transistor SST, a plurality of memory cells F1 to F16, and a drain select transistor DST, which are connected in series between the source line SL and the first bit line BL1. At least one source select transistor SST and at least one drain select transistor DST may be included in one string ST, and memory cells of which number is greater than that of the memory cells F1 to F16 shown in the drawing may be included in the one string ST.

A source of the source select transistor SST may be connected to the source line SL, and a drain of the drain select transistor DST may be connected to the first bit line BL1. The memory cells F1 to F16 may be connected in series between the source select transistor SST and the drain select transistor DST. Gates of source select transistors SST included in different strings ST may be connected to the source select line SSL, gates of drain select transistors DST included in different strings ST may be connected to the drain select line DSL, and gates of memory cells F1 to F16 included in different strings ST may be connected to a plurality of word lines WL1 to WL16. A group of memory cells connected to the same word line among memory cells included in different strings ST may be referred as a page PPG. Therefore, pages PPG of which number corresponds to that of the word lines WL1 to WL16 may be included in the memory block 110.

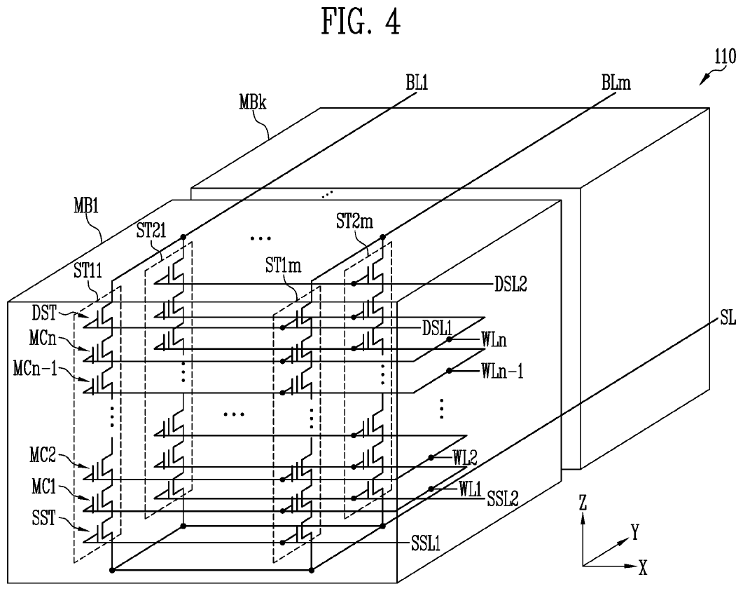

FIG. 4 is a diagram illustrating an embodiment of a three-dimensionally configured memory block.

Referring to FIG. 4, the memory cell array 100 may include a plurality of memory blocks MB1 to MBk 110. The memory block 110 may include a plurality of strings ST11 to ST1m and ST21 to ST2m. In an embodiment, each of the plurality of strings ST11 to ST1m and ST21 to ST2m may be formed in an ‘I’ shape or a ‘U’ shape. In a first memory block MB1, m strings may be arranged in a row direction (X direction). Although a case where two strings are arranged in a column direction (Y direction) is illustrated in FIG. 4, this is for convenience of description, and three or more strings may be arranged in the column direction (Y direction).

Each of the plurality of strings ST11 to ST1m and ST21 to ST2m may include at least one source select transistor SST, first to nth memory cells MC1 to MCn, and at least one drain select transistor DST.

The source select transistor SST of each string may be connected between a source line SL and memory cells MC1 to MCn. Source select transistors of strings arranged on the same row may be connected to the same source select line. Source select transistors of strings ST11 to ST1m arranged on a first row may be connected to a first source select line SSL1. Source select transistors of strings ST21 to ST2m arranged on a second row may be connected to a second source select line SSL2. In another embodiment, the source select transistors of the strings ST11 to ST1m and ST21 to ST2m may be commonly connected to one source select line.

The first to nth memory cells MC1 to MCn of each string may be connected in series to each other between the source select transistor SST and the drain select transistor DST. Gates of the first to nth memory cells MC1 to MCn may be respectively connected to first to nth word lines WL1 to WLn.

In an embodiment, at least one of the first to nth memory cells MC1 to MCn may be used as a dummy memory cell. When the dummy memory cell is provided, a voltage or current of a corresponding string can be stably controlled. Accordingly, the reliability of data stored in the memory block 110 can be improved.

The drain select transistor DST of each string may be connected between a bit line and the memory cells MC1 to MCn. Drain select transistors DST of strings arranged in the row direction may be connected to a drain select line extending in the row direction. Drain select transistors DST of the strings ST11 to ST1m on the first row may be connected to a first drain select line DSL1. Drain select transistors DST of the strings ST21 to ST2m on the second row may be connected to a second drain select line DSL2.

A program operation may be performed on a selected memory block (e.g., MB1) among the plurality of memory blocks MB1 to MBn 110. The selected memory block (e.g., MB1) may be defined as a target block, and each of memory blocks sharing bit lines and word lines with the target block may be defined as a share block.

In the program operation of the target block, the same operating voltage as the target block is applied to the bit lines and the word lines of the share block, and therefore, unintended holes may be introduced into channels of strings included in the share block. Such a phenomenon may occur not only in the program operation of the target block but also in read and erase operations. A threshold voltage distribution of the share block may be changed by this phenomenon. Due to the changed threshold voltage distribution, a read operation of the share block may fail in the read operation. That is, a relatively large number of fail bits may be included in data read by the read operation of the share block, which is performed just after an operation is performed on the target block. This is referred to as a first page read fail (1^{st} page read fail).

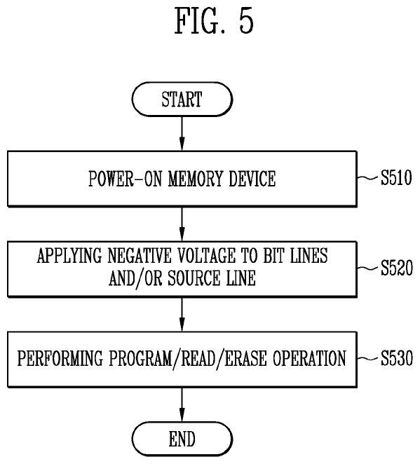

FIG. 5 is a flowchart illustrating an operating method of the memory device in accordance with an embodiment of the present disclosure.

The operating method of the memory device in accordance with an embodiment of the present disclosure will be described as follows with reference to FIGS. 2 to 5.

In step S510, when the memory device 1100 is powered-on as a power voltage is supplied to the memory device from outside the memory device, the memory device 1100 reads system data stored in a memory block defined as a system block among the plurality of memory blocks MB1 to MBk 110 included in the memory cell array 100. The system data may include parameters associated with at least one operation among a read operation, a program operation, and an erase operation of the memory device 1100. The read system data may be transmitted to the memory controller 1200 shown in FIG. 1.

In step S520, a negative voltage applying operation of applying a negative voltage Vneg to the bit lines BL1 to BLm or the source line SL of the plurality of memory blocks MB1 to MBk 110 included in the memory cell array 100 or the bit lines BL1 to BLm and the source line SL is performed.

For example, after a power-on operation of the memory device 1100, the control logic 300 controls the negative voltage generating circuit 400 to apply the negative voltage Vneg to the bit lines BL1 to BLm or the source line SL of the plurality of memory blocks MB1 to MBk 110 or the bit lines BL1 to BLm and the source line SL.

In the negative voltage applying operation, the voltage generating circuit 210 generates an operating voltage to be applied to the drain select line DSL and the source select line SSL, and the row decoder 220 applies the operating voltage generated by the voltage generating circuit 210 to the drain select line DSL and the source select line SSL of the memory blocks MB1 to MBk 110. Accordingly, the drain select transistors DST and the source select transistors SST of the memory blocks MB1 to MBk 110 are turned on.

Thus, holes in channels of strings ST included in each of the memory blocks MB1 to MBk 110 can be removed by the negative voltage Vneg applied to the bit lines BL1 to BLm or the source line SL or the bit lines BL1 to BLm and the source line SL.

In step S530, a general operation is performed on a selected memory block among the memory blocks MB1 to MBk 110 after the negative voltage applying operation. That is, a program, read, or erase operation of the selected memory block is performed.

As described above, in accordance with an embodiment of the present disclosure, holes remaining in channels of the memory blocks MB1 to MBk 110 are removed by performing the negative voltage applying operation of applying the negative voltage Vneg to the bit lines EL1 to BLm or the source line SL of the memory blocks MB1 to MBk 110 or the bit lines BL1 to BLm and the source line SL after the power-on operation of the memory device 1100, so that the first page read fail can be prevented.

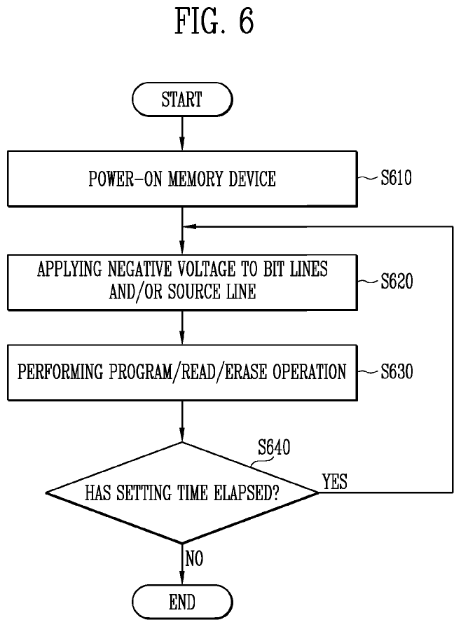

FIG. 6 is a flowchart illustrating an operating method of the memory device in accordance with another embodiment of the present disclosure.

The operating method of the memory device in accordance with the another embodiment of the present disclosure will be described as follows with reference to FIGS. 2 to 4 and 6.

In step S610, when the memory device 1100 is power-on as a power voltage is supplied to the memory device from outside the memory device, the memory device 1100 reads system data stored in a memory block defined as a system block among the plurality of memory blocks MB1 to MBk 110 included in the memory cell array 100. The system data may include parameters associated with at least one operation among a read operation, a program operation, and an erase operation of the memory device 1100. The read system data may be transmitted to the memory controller 1200 shown in FIG. 1.

In step S620, a negative voltage applying operation of applying a negative voltage Vneg to the bit lines BL1 to BLm or the source line SL of the plurality of memory blocks MB1 to MBk 110 included in the memory cell array 100 or the bit lines BL1 to BLm and the source line SL is performed.

For example, after a power-on operation of the memory device 1100, the control logic 300 controls the negative voltage generating circuit 400 to apply the negative voltage Vneg to the bit lines BL1 to BLm or the source line SL of the plurality of memory blocks MB1 to MBk 110 or the bit lines BL1 to BLm and the source line SL.

In the negative voltage applying operation, the voltage generating circuit 210 generates an operating voltage to be applied to the drain select line DSL and the source select line SSL, and the row decoder 220 applies the operating voltage generated by the voltage generating circuit 210 to the drain select line DSL and the source select line SSL of the memory blocks MB1 to MBk 110. Accordingly, the drain select transistors DST and the source select transistors SST of the memory blocks MB1 to MBk 110 are turned on.

Thus, holes in channels of strings ST included in each of the memory blocks MB1 to MBk 110 can be removed by the negative voltage Vneg applied to the bit lines BL1 to BLm or the source line SL or the bit lines BL1 to BLm and the source line SL.

In step S630, a general operation is performed on a selected memory block among the memory blocks MB1 to MBk 110 after the negative voltage applying operation. That is, a program, read or erase operation of the selected memory block is performed.

In step S640, it is checked whether a setting time has elapsed after the above-described negative voltage applying operation (S620) is performed. When the setting time elapses after the negative voltage applying operation (S620) is performed (YES), the above-described negative voltage applying operation (S620) is re-performed. The negative voltage applying operation may be preferably performed when the memory device 1100 is in a standby state.

When the setting time does not elapse after the negative voltage applying operation (S620) is performed (NO), the memory device 1100 may stand by in the standby state.

As described above, in accordance with the another embodiment of the present disclosure, holes remaining in channels of the memory blocks MB1 to MBk 110 are removed by performing the negative voltage applying operation of applying the negative voltage Vneg to the bit lines BL1 to BLm or the source line SL of the memory blocks MB1 to MBk 110 or the bit lines BL1 to BLm and the source line SL after the power-on operation of the memory device 1100, so that the first page read fail can be prevented. In addition, the negative voltage applying operation can be re-performed when the setting time elapses after the negative voltage applying operation is performed.

In still another embodiment, the negative voltage applying operation may be re-performed when a number of times a program/erase cycle of the memory blocks MB1 to MBk 110 is repeated exceeds a setting number of times after the negative voltage applying operation is performed. For example, after the power-on operation of the memory device 1100, the negative voltage applying operation is performed, and a general operation of the memory blocks MB1 to MBk 110 is performed. When the number of times the program/erase cycle of the memory blocks MB1 to MBk 110 is repeated exceeds the setting number of times, the negative voltage applying operation may be re-performed.

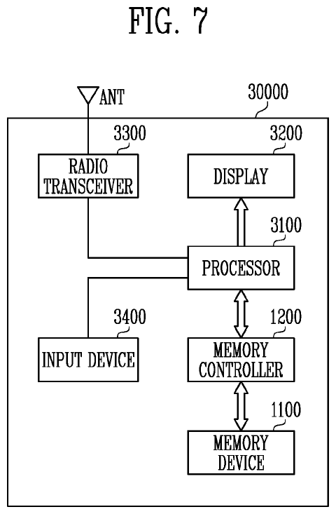

FIG. 7 is a diagram illustrating another embodiment of the memory system.

Referring to FIG. 7, the memory system 30000 may be implemented as a cellular phone, a smart phone, a tablet PC, a personal digital assistant (PDA), or a wireless communication device. The memory system 30000 may include a memory device 1100 and a memory controller 1200 capable of controlling an operation of the memory device 1100. The memory controller 1200 may control a data access operation of the memory device 1100, e.g., a program operation, an erase operation, a read operation, or the like under the control of a processor 3100.

Data programmed in the memory device 1100 may be output through a display 3200 under the control of the memory controller 1200.

A radio transceiver 3300 may transmit/receive radio signals through an antenna ANT. For example, the radio transceiver 3300 may change a radio signal received through the antenna ANT into a signal that can be processed by the processor 3100. Therefore, the processor 3100 may process a signal output from the radio transceiver 3300 and transmit the processed signal to the memory controller 1200 or the display 3200. The memory controller 1200 may transmit the signal processed by the processor 3100 to the memory device 1100. Also, the radio transceiver 3300 may change a signal output from the processor 3100 into a radio signal, and output the changed radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the memory controller 1200, data output from the radio transceiver 3300, or data output from the input device 3400 can be output through the display 3200.

In some embodiments, the memory controller 1200 capable of controlling an operation of the memory device 1100 may be implemented as a part of the processor 3100, or be implemented as a chip separate from the processor 3100. In addition, the memory controller 1200 may be implemented as an example of the memory controller 1200 shown in FIG. 1, and the memory device 1100 may be implemented as an example of the memory device 1100 shown in FIG. 2.

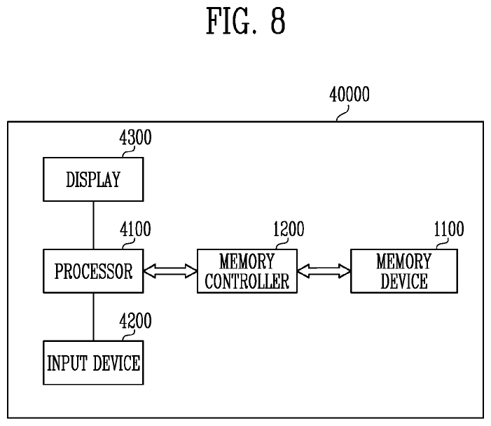

FIG. 8 is a diagram illustrating another embodiment of the memory system.

Referring to FIG. 8, the memory system 40000 may be implemented as a personal computer (PC), a tablet PC, a net-book, an e-reader, a personal digital assistant (PDA), a portable multi-media player (PMP), an MP3 player, or an MP4 player.

The memory system 40000 may include a memory device 1100 and a memory controller 1200 capable of controlling a data processing operation of the memory device 1100.

A processor 4100 may output data stored in the memory device 1100 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the memory controller 1200. In some embodiments, the memory controller 1200 capable of controlling an operation of the memory device 1100 may be implemented as a part of the processor 4100, or be implemented as a chip separate from the processor 4100. In addition, the memory controller 1200 may be implemented as an example of the memory controller 1200 shown in FIG. 1, and the memory device 1100 may be implemented as an example of the memory device 1100 shown in FIG. 2.

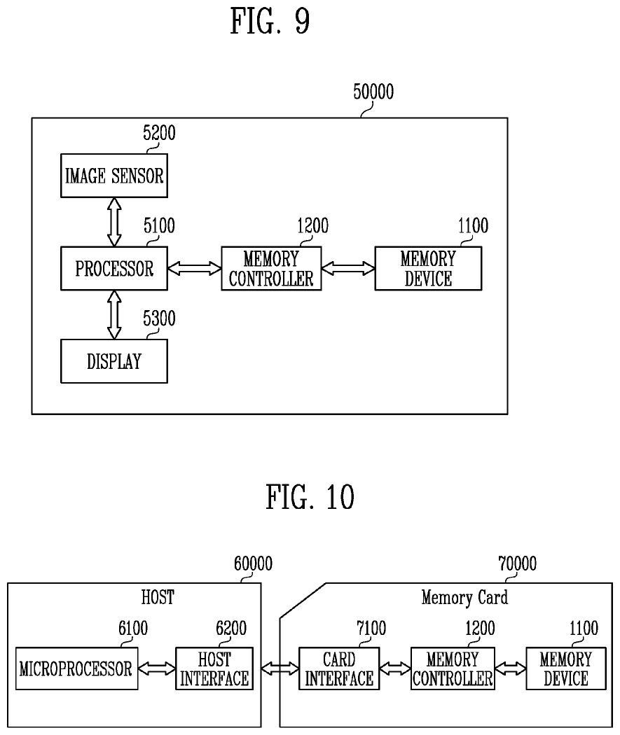

FIG. 9 is a diagram illustrating another embodiment of the memory system.

Referring to FIG. 9, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a memory controller 1200 capable of controlling a data processing operation of the memory device 1100, e.g., a program operation, an erase operation, or a read operation.

An image sensor 5200 of the memory system 50000 may convert an optical image into digital signals, and the converted digital signals may be transmitted to a processor 5100 or the memory controller 1200. Under the control of the processor 5100, the converted digital signals may be output through a display 5300, or be stored in the memory device 1100 through the memory controller 1200. In addition, data stored in the memory device 1100 may be output through the display 5300 under the control of the processor 5100 or the memory controller 1200.

In some embodiments, the memory controller 1200 capable of controlling an operation of the memory device 1100 may be implemented as a part of the processor 5100, or be implemented as a chip separate from the processor 5100. In addition, the memory controller 1200 may be implemented as an example of the memory controller 1200 shown in FIG. 1, and the memory device 1100 may be implemented as an example of the memory device 1100 shown in FIG. 2.

FIG. 10 is a diagram illustrating another embodiment of the memory system.

Referring to FIG. 10, the memory system 70000 may be implemented as a memory card or a smart card. The memory system 70000 may include a memory device 1100, a memory controller 1200, and a card interface 7100.

The memory controller 1200 may control data exchange between the memory device 1100 and the card interface 7100. In some embodiments, the card interface 7100 may be a secure digital (SD) card interface or a multi-media card (MMC) interface, but the present disclosure is not limited thereto. In addition, the memory controller 1200 may be implemented as an example of the memory controller 1200 shown in FIG. 1, and the memory device 1100 may be implemented as an example of the memory device 1100 shown in FIG. 2.

The card interface 7100 may interface data exchange between a host 60000 and the memory controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the memory controller 1200 under the control of a microprocessor 6100.

In accordance with the present disclosure, holes remaining in channels of memory blocks are removed by applying a negative voltage to bit lines and a source line of the memory blocks after a power-on operation of the memory device, so that a first page read fail of a share block can be prevented.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a memory cell array including a plurality of memory blocks;
peripheral circuits configured to perform a program operation, a read operation, or an erase operation on the plurality of memory blocks;
a negative voltage generating circuit configured to apply a negative voltage to bit lines or a source line of the plurality of memory blocks or the bit lines and the source line in a negative voltage applying operation; and
control logic configured to control the peripheral circuits to perform the program operation, the read operation, or the erase operation, and control the negative voltage generating circuit to perform the negative voltage applying operation after a power-on operation.

2. The memory device of claim 1, wherein the peripheral circuits are configured to turn on drain select transistors and source select transistors of each of the plurality of memory blocks in the negative voltage applying operation.

3. The memory device of claim 1, wherein the control logic is configured to control the negative voltage generating circuit to re-perform the negative voltage applying operation when a setting time elapses after the negative voltage applying operation is performed.

4. The memory device of claim 3, wherein the control logic is configured to control the negative voltage generating circuit to re-perform the negative voltage applying operation during a standby interval after the setting time elapses.

5. The memory device of claim 1, wherein the control logic is configured to control the negative voltage generating circuit to re-perform the negative voltage applying operation when a number of times a program/erase cycle of the plurality of memory blocks is repeated exceeds a setting number of times after the negative voltage applying operation is performed.

6. A method of operating a memory device, the method comprising:
performing a power-on operation to power up the memory device as a power voltage is supplied to the memory device from outside the memory device; and
performing a negative voltage applying operation of applying a negative voltage to bit lines or a source line of the plurality of memory blocks or the bit lines and the source line.

7. The method of claim 6, wherein, in the performing of the negative voltage applying operation, drain select transistors and source select transistors of each of the plurality of memory blocks are turned on such that the negative voltage is applied to channels of each of the plurality of memory blocks.

8. The method of claim 6, further comprising:
after the performing of the negative voltage applying operation,
performing a general operation including a program operation, a read operation, or an erase operation on a selected memory block among the plurality of memory blocks.

9. The method of claim 8, further comprising re-performing the negative voltage applying operation when a setting time elapses after performing the negative voltage applying operation.

10. The method of claim 8, further comprising re-performing the negative voltage applying operation when a number of times a program/erase cycle of the plurality of memory blocks is repeated exceeds a setting number of times after performing the negative voltage applying operation.

11. A method of operating a memory device, the method comprising:
performing a power-on operation to power up the memory device as a power voltage is supplied to the memory device from outside the memory device;
performing a negative voltage applying operation of applying a negative voltage to bit lines or a source line of the plurality of memory blocks or the bit lines and the source line; and
re-performing the negative voltage applying operation when a setting time elapses after the negative voltage applying operation is performed.

12. The method of claim 11, wherein, in the performing of the negative voltage applying operation, drain select transistors and source select transistors of each of the plurality of memory blocks are turned on such that the negative voltage is applied to channels of each of the plurality of memory blocks.

13. The method of claim 11, further comprising re-performing the negative voltage applying operation when a number of times a program/erase cycle of the plurality of memory blocks is repeated exceeds a setting number of times after performing the negative voltage applying operation.
